(19) United States
(12) Patent Application Publication
(10) Pub. No.: US 2026/0197962 A1
(43) Pub. Date: Jul. 9, 2026

(54) LATCH FOR SERVER SLIDES

(71) Applicant: Asia Pacific CIS (Wuxi) Co., Ltd., Wuxi (CN)

(72) Inventors: Jun Tong, Wuxi (CN); Sheng Pang, Wuxi (CN); Jichao Wang, Wuxi (CN)

(21) Appl. No.: 19/417,094

(22) Filed: Dec. 11, 2025

(30) Foreign Application Priority Data
Jan. 7, 2025 (CN) 202510020580.9

(51) Int. Cl. H05K 7/14; F16C 29/10; F16M 11/20

(52) U.S. Cl. CPC H05K 7/1489; F16C 29/10; F16M 11/2092; H05K 7/1415

(57) ABSTRACT

A latch assembly for a server slide can include a latch biased toward a first latch position and movable between the first latch position and a second latch position, a retention bearing including a fixed portion and a rotatable portion circumferentially surrounding the fixed portion to be rotatable around the fixed portion, and a handle moveable between a first and second handle positions to move the latch from the first latch position to the second latch position. The latch can engage the retention bearing at the rotatable portion to prevent telescopic movement of the first rail relative to the second rail in a first direction. As the handle is moved from the first handle position to the second handle position the rotatable portion can rotate to release the latch from engagement with the retention bearing, to permit telescopic movement of the first rail relative to the second rail.

### CROSS-REFERENCE TO RELATED APPLICATIONS

This application claims priority to Chinese Invention Patent Application No. 202510020580.9, filed January 7, 2025, which is herein incorporated by reference in its entirety.

### TECHNICAL FIELD

The disclosure relates to a server rack, in particular to a front latch for a server slide.

### BACKGROUND

Slides (e.g., server rack slides) may permit a user to selectively access a server chassis secured within a server rack. The slides may support the server chassis and permit the user to expand the slides (e.g., telescope slides away from server rack) to access the server chassis (e.g., for maintenance). In some examples, the slides may include a front latch to retain the server chassis within the server rack (e.g., in a contracted position). In some cases, due to force applied to the front latch (e.g., via blind-mate of components at a rear of the server chassis) actuation of the front latch may be difficult. Thus, the user may need to apply a large force to the front latch to actuate the front latch and extend the slides away from the server rack to access the server chassis.

### SUMMARY

Some aspects of the disclosure provide a server slide. The server slide can include a first rail, a second rail telescopically engaged with the first rail, and a latch assembly secured to a first end of the first rail. The latch assembly can include a latch that is biased toward a first latch position and movable between the first latch position and a second latch position, a retention bearing including a fixed portion and a rotatable portion circumferentially surrounding the fixed portion to be rotatable around the fixed portion, and a handle that is moveable between a first handle position and a second handle position to move the latch from the first latch position to the second latch position. With the first and second rails in a locked configuration, the latch in the first latch position, and the handle in the first handle position, the latch engages the retention bearing at the rotatable portion to prevent telescopic movement of the first rail relative to the second rail in a first direction. As the handle is moved from the first handle position to the second handle position, the rotatable portion rotates to release the latch from engagement with the retention bearing, to permit telescopic movement of the first rail relative to the second rail in the first direction.

Some aspects of the disclosure provide a method of operating a server slide. The method can include engaging a handle of a latch assembly in a first position, in which the latch assembly prevents telescopic movement of a first rail relative to a second rail in a first direction, sliding the handle from the first position to a second position, to disengage a latch of the latch assembly from a rotatable portion of a retention bearing, the retention bearing including a fixed portion that is circumferentially surrounded by the rotatable portion, and with the handle in the second position, pulling the handle of the latch assembly to move the server slide from a retracted position to an expanded position.

Some aspects of the disclosure provide a latch assembly for telescoping engagement of a first rail and a second rail. The latch assembly can include a latch defining a latch recess, the latch being biased toward a first latch position and secured to the first rail to be movable between the first latch position and a second latch position. The assembly also includes a retention bearing including a fixed portion secured to the second rail and a rotatable portion circumferentially surrounding the fixed portion to be rotatable around the fixed portion. The latch, in the first latch position, may be aligned to receive the rotatable portion into the latch recess to secure the first rail against telescoping movement relative to the second rail. Further, the latch, in the second latch position, may be aligned to clear the retention bearing to permit telescoping movement of the first rail relative to the second rail. With the latch in the first latch position and the rotatable portion received into the latch recess, the rotatable portion may be rotatable by the latch, to move the latch circumferentially around the retention bearing from the first latch position toward the second latch position.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is a diagrammatic view of a server system including server slides having a latch assembly according to aspects of the present disclosure.

FIG. 2 is an axonometric view of an example configuration of one of the server slides of FIG. 1.

FIG. 3 is an enlarged first-side axonometric partial view of a first end of the server slide of FIG. 2.

FIG. 4 is a cross-sectional view of a portion of the server slide of FIG. 2 depicting a retention bearing for use with the latch assembly.

FIG. 5 is a side elevation view of the latch assembly of the server slide of FIG. 2.

FIG. 6 is a side elevation view of the latch assembly of the server slide of FIG. 2 with a handle rendered transparent to show interior components.

FIG. 7 is an enlarged first-end top view of the server slide of FIG. 2.

FIG. 8 is side partial view of the server slide of FIG. 2, with the latch assembly in a first position, engaged with the retention bearing of FIG. 4.

FIG. 9 is side partial view of the server slide of FIG. 2, with the latch assembly in a second position.

FIG. 10 is another side partial view of the server slide of FIG. 2, with the latch assembly in the second position.

FIG. 11 is a side partial view of the server slide of FIG. 2, with the latch assembly in the first position, disengaged from the retention bearing of FIG. 4.

FIG. 12 is a first-side partial view of another example of a latch assembly of the server slide of FIG. 2 including the retention bearing of FIG. 4.

FIG. 13 is a first-side partial view of another example of a latch assembly of the server slide of FIG. 2 including the retention bearing of FIG. 4.

FIG. 14 is a first-side partial view of yet another example of a latch assembly of the server slide of FIG. 2 including the retention bearing of FIG. 4.

### DETAILED DESCRIPTION

The following discussion is presented to enable a person skilled in the art to make and use embodiments of the invention. Given the benefit of this disclosure, various modifications to the illustrated embodiments will be readily apparent to those skilled in the art, and the principles herein can be applied to other embodiments and applications without departing from embodiments of the invention. Thus, embodiments of the invention are not intended to be limited to embodiments shown, but are to be accorded the widest scope consistent with the principles and features disclosed herein.

The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

In some examples, a server slide may support one or more server chassis within a server rack to permit access to the server (e.g., within the server chassis). For example, the server slide may permit a user to access the server for installation, maintenance, or replacement. In some examples, the server slide may include a latch assembly (e.g., a front latch assembly) to prevent accidental telescopic movement (e.g., expansion/contraction) of the server slide, which may correspond to unwanted movement of the server chassis.

In some examples, the server slide may include a first rail nested within a second rail. In some examples, the first rail is configured to telescope within the second rail to expand or contract an overall length of the server slide. In some examples, the latch assembly is configured to prevent the accidental removal or telescopic movement of the first rail with respect to the second rail. For example, the latch assembly can be configured to selectively engage or disengage a portion of the second rail to prevent movement of the first rail with respect to the second rail.

In some examples, the latch assembly may include a mounting bracket and a handle that together retain a latch. The latch assembly may be moveable between a first position (e.g., an engaged position) and a second position (e.g., a disengaged position) via actuation of a handle attached to the latch assembly.

In some examples, in a first position, the latch may engage a retention bearing mounted to the second rail. For example, the latch may partially surround the retention bearing so that movement of the first rail with respect to the second rail is prohibited. However, in a second position, the latch may disengage the retention bearing so that movement of the first rail with respect to the second rail is permitted. In some examples, the retention bearing may have a rotating portion that is engaged by the latch to lock the first and second rail against telescoping movement, and that can rotate to facilitate easier movement of the latch to a disengaged configuration.

In some examples, the handle may include an embossed portion configured to engage with a portion of the latch through movement (e.g., linear movement) of the handle. Thus, as an operator pulls on the handle from a first position to a second position, the embossed portion may apply a force to the latch, which moves the latch from the first position to the second position. In some examples, the latch may be biased towards the first position via one or more biasing elements so that a pulling force applied to the handle overcomes the biasing force of the biasing elements to move the latch into the second position. Correspondingly, if an operator were to release the handle when in the second position, the handle may automatically return to the first position (e.g., via force from the biasing elements).

In some examples, when the first rail is retracted within the second rail, the operator may grasp the handle and pull the handle towards the operator. This movement of the handle can cause the embossed portion of the handle to engage the latch and move the latch from the first (engaged) position to the second (disengaged) position against the biasing force of the biasing element(s). Further, with this and other designs, free rotation of part of the retention bearing may lower the amount of force required to be placed on the handle by the operator as compared to conventional designs. Once the operator has pulled the handle into the second position, the latch may no longer prevent relative movement of the first and second rails and the operator may pull the handle to extend the first rail out of the second rail, thereby extending the server chassis out of the server rack.

In some examples, to return the server chassis into the server rack, the operator may release the handle, which may automatically return to the first position (e.g., as driven by one or more biasing elements). Correspondingly, the latch may automatically return to the first (engaged) position. The operator may then push the server chassis (e.g., retract the first rail into the second rail) into the server rack. In some examples, when the latch contacts the retention bearing, the latch may be automatically moved until the latch is locked around the retention bearing (e.g., in the first (engaged) position). In this regard, for various latch assemblies, free rotation of part of the retention bearing may also help to lower the amount of force required, as compared to conventional designs. Thus, the server chassis can be easily and securely retained within the server rack.

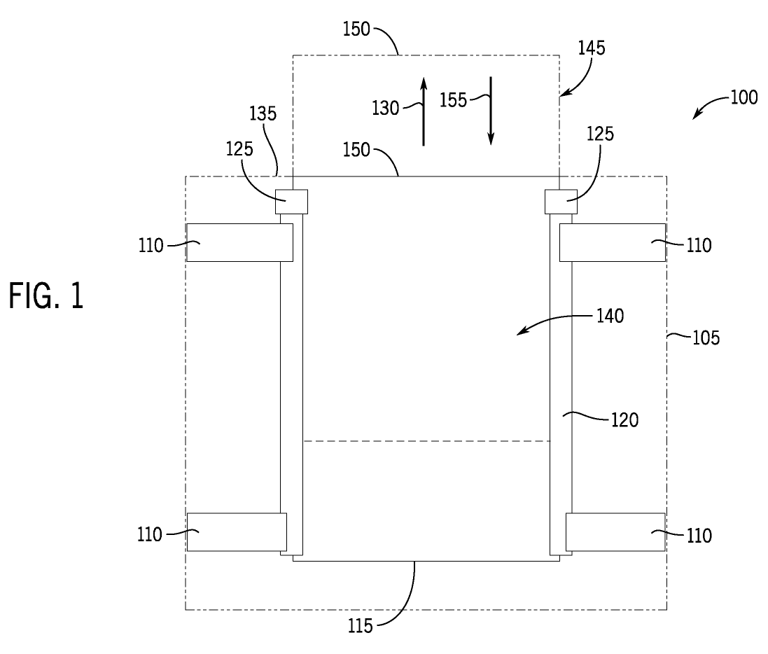

FIG. 1 shows an example of a server system 100 including a server chassis 115 secured within a server rack 105. In some examples, the server chassis 115 may be slidable between a first position 140 (e.g., a retracted position) and a second position 145 (e.g., an extended position, as shown with dashed lines in FIG. 1). In some examples, in the first position 140, an edge 150 of the server chassis 115 is substantially even with an edge 135 of the server rack 105. Correspondingly, in the second position 145, the edge 150 of the server chassis 115 may be extended past the edge 135 of the server rack 105 (e.g., in the direction shown by arrow 130).

In some examples, to permit slidable movement of the server chassis 115, the server system 100 may include one or more server slides 120. The server slides 120 may be secured between one or more supports 110 of the server rack 105 and the server chassis 115 to slidably secure the server chassis 115 to the server rack 105. For example, the server slides 120 may facilitate slidable movement of the server chassis 115 between the first position 140 and the second position 145 (e.g., as shown by arrow 130) via telescopic movement of the server slides 120.

In some examples, the server slides 120 may include a one or more nested slide rails to permit extension of the server slides 120. For example, the server slides 120 may include a first rail nested within and slidable relative to a second rail. In some examples, the first rail is configured to telescope within the second rail to expand or contract an overall length of the server slides 120, which in turn may move the server chassis 115 between the first position 140 and the second position 145.

In some examples, the server slides 120 may include a latch assembly 125 (e.g., a front latch assembly) adjacent to the edge 150 of the server chassis 115. The latch assembly 125 may assist in preventing accidental removal or telescopic movement of the first rail with respect to the second rail (e.g., corresponding to movement of the server chassis 115). In one particular example, the latch assembly 125 may automatically lock the first rail to the second rail to restrict relative movement between the first and second rails (e.g., when the server chassis 115 is in the first position 140). Correspondingly, an operator may selectively unlock relative movement between the first and second rails via the latch assembly 125 (e.g., to permit movement of the server chassis 115 from the first position 140 to the second position 145 as shown by arrow 130).

Further, when in the second position 145, the latch assembly 125 may allow movement of the server chassis 115 from the second position 145 to the first position 140 (e.g., as shown by arrow 155). However, in some examples, a secondary latch assembly may lock the server chassis in the second position 145 and may need to be unlocked to permit movement of the server chassis into the first position 140. In some cases, the latch assembly 125 may also automatically lock when reaching the first position 140.

In some examples, a server chassis 115 may include a set of multiple server slides 120 (e.g., with one of the server slides 120 on each of two opposing lateral sides of the chassis). However, in some examples, only one of the set of server slides 120 may include the latch assembly 125. In other examples, multiple of the server slides 120 may include the latch assembly 125.

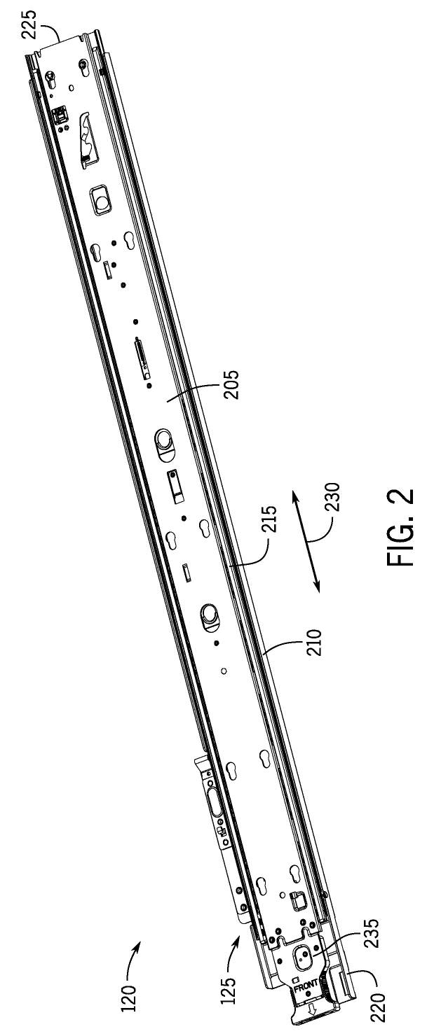

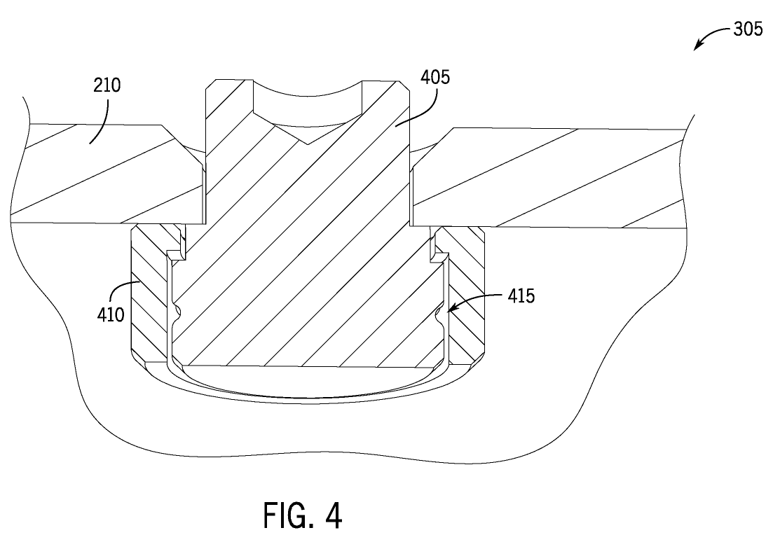

FIGS. 2-4 illustrate some examples of a server slide 120 including the latch assembly 125. As mentioned previously, the server slide 120 may include a first rail 205 (e.g., an inner rail) and a second rail 210 (e.g., an outer, fixed rail). In some examples, the server slide 120 may further include a third rail 215 (e.g., an intermediate rail), which may be arranged between the first rail 205 and the second rail 210. In some examples, the first rail 205 may be nested within the third rail 215, which in turn may be nested within the second rail 210. Thus, the first rail 205 and the third rail 215 may be telescopically moveable relative to the second rail 210 and each other.

In some examples, the second rail 210 may be fixed to the supports 110 so that the second rail 210 is not moveable, but is instead fixed in position. For example, the second rail 210 may be fixed to the supports 110 via one or more pins, which may extend from the second rail 210 into the supports 110. In other examples, the second rail 210 may include one or more mounting brackets to secure the server slides 120 to the supports 110.

The server slide 120 may include a first end 220 and a second end 225, with the first rail 205 and the third rail 215 able to telescope out from the first end 220 to extend an overall length of the server slide 120. As also discussed above, this telescoping movement may correspond to movement of the server chassis 115 into the second position 145. Correspondingly, the first rail 205 and the third rail 215 are able to retract relative to the first end 220 to reduce an overall length of the server slide 120, which corresponds to movement of the server chassis 115 into the first position 140. Put differently, the telescopic relationship between the first rail 205, second rail 210, and the third rail 215 permits the server slides 120 to extend or retract as shown by arrow 230 to move the server chassis 115 between the first position 140 and the second position 145.

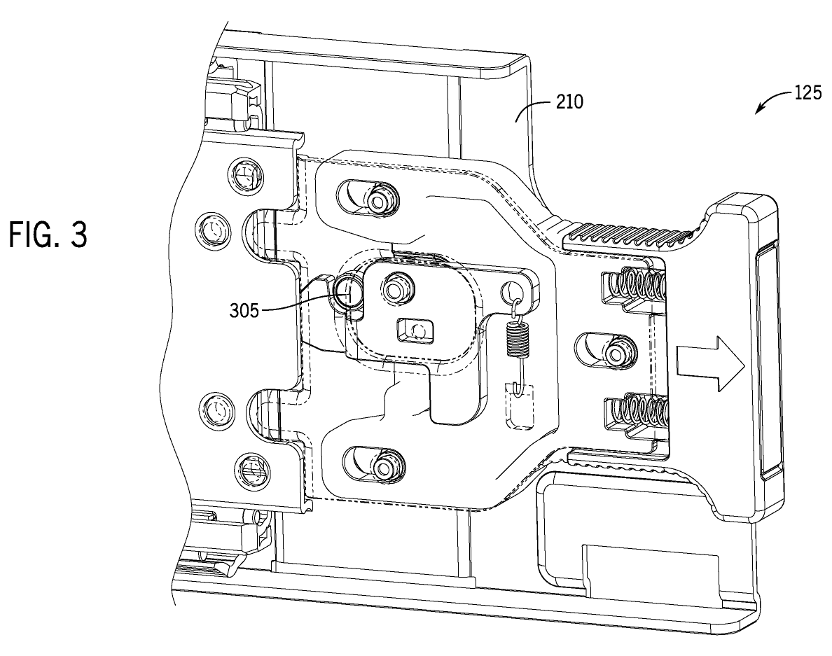

In some examples, the latch assembly 125 may be secured to the first end 220 of the server slide 120 via a mounting bracket 235 extending from the first end of the first rail 205. In one particular example, the latch assembly 125 may be arranged between the mounting bracket 235 and the second rail 210. Additionally, the first end of the second rail 210 may include a retention bearing 305 configured to receive and retain a portion of the latch assembly 125 when the server slide 120 is in a retracted position (e.g., as shown in FIG. 3) to prevent inadvertent telescopic movement of the server slide 120. Alternatively, in different examples, similar components can be arranged at other locations along various other rails.

In some examples, a first (e.g., a fixed) portion 405 of the retention bearing 305 may extend through the second rail 210 to secure the retention bearing 305 to the second rail 210. Further, the first portion 405 of the retention bearing 305 may be fixed (e.g., unable to rotate relative to the second rail 210). Correspondingly, the retention bearing 305 may include a second (e.g., rotatable) portion 410 that circumferentially surrounds an end of the first portion 405. In some examples, the second portion 410 may be configured to be rotatable with respect to the first portion 405 (e.g., about an axis formed by the first portion 405), including via the provision of particular clearances or bearing surfaces between the portions 405, 410. For example, a lubrication groove 415 between the first and second portions 405, 410 may be filled with a low-friction fluid (e.g., oil) to permit particularly smooth rotation of the second portion 410 with respect to the first portion 405.

Thus, in some examples, the second portion 410 of the retention bearing 305 may rotate during disengagement of the latch assembly 125 to reduce the force required to disengage the latch assembly. For example, as further discussed below a hooked or other shoulder structure of the latch assembly 125 (or another latch assembly) may be configured to engage the second portion 410 of the retention bearing 305 to mechanically block movement of one rail relative to another. Further, the rotation of the second portion 410 of the retention bearing 305 during operation can help to reduce the force required to intentionally release the hooked (or other) structure of the latch assembly 125 from the retention bearing 305 (e.g., during application of translational force on a hook structure).

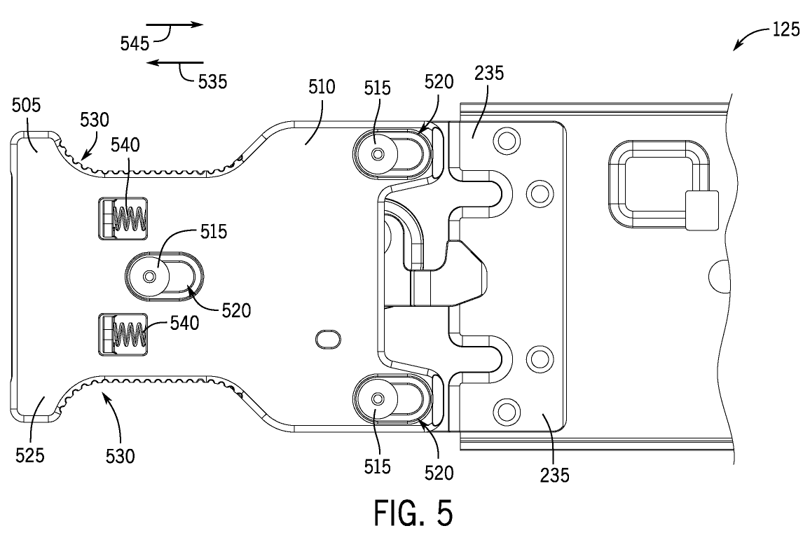

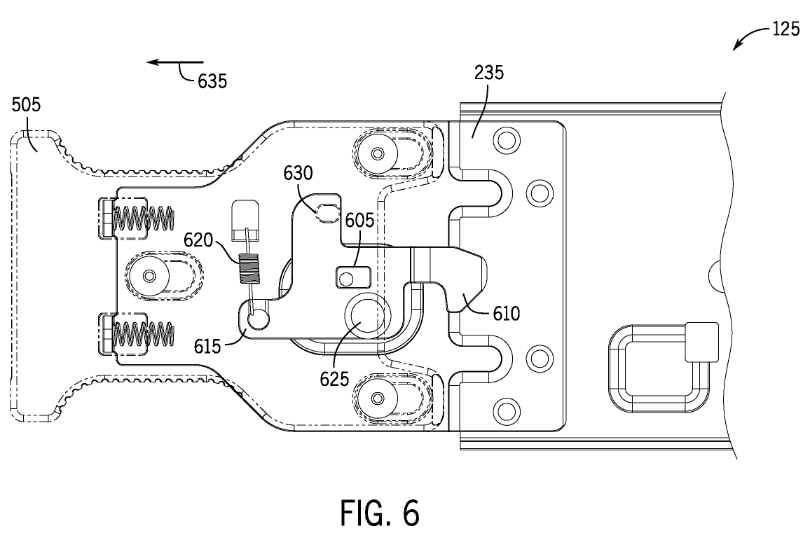

FIG. 5 shows an example of a handle 505 of the latch assembly 125. The handle 505 may be configured to actuate the latch assembly 125 in order to rotate a latch 605 (see, e.g., FIG. 6) from a first (locked) position, where the latch 605 engages the retention bearing 305, to a second (unlocked) position, where the latch 605 disengages the retention bearing 305.

In some examples, the handle 505 may include a body portion 510. The body portion 510 may be slidably secured to the mounting bracket 235 via one or more rivets 515 arranged in one or more corresponding slots 520 defined by the body portion 510. In some examples, a width (e.g., size) of the slots 520 may define the bounds of movement of the handle 505. Thus, when the rivets 515 are at a first end of the slots 520, the latch assembly 125 may be in a first (locked) position and when the rivets 515 are at a second end of the slots 520, the latch assembly 125 may be in a second (unlocked) position.

In some examples, in order to permit a user to grasp and manipulate the handle, the handle 505 may include a grip portion 525. In some examples, the grip portion 525 may include one or more surface textures configured to provide an improved grip to a user. Further, the grip portion 525 may include one or more cutouts 530 configured to permit a user to grasp and manipulate the handle 505. For example, a user may grasp and move the handle 505 in the direction shown by arrow 535 in order to transition the latch assembly 125 from the first (locked) position to the second (unlocked) position (e.g., in order to permit telescopic movement of the slide rail(s)).

Further, in some examples, once the user has moved the latch assembly 125 into the second (unlocked) position, the user may release the handle 505, which may automatically return to the first (locked) position. For example, the handle 505 may include one or more biasing elements 540 (e.g., coil springs or other known spring types) configured to return the handle to a home position (e.g., corresponding to a first (locked) position of the latch assembly 125. In some examples the one or more biasing elements 540 may be arranged between the mounting bracket 235 and the handle 505 so that movement of the handle in the direction shown by arrow 535 compresses the biasing elements. Thus, when the user releases the handle 505, the biasing elements 540 decompress and automatically move the handle in the direction shown by arrow 545 (e.g., to return the latch to the first (locked) position).

FIG. 6 shows an example of the latch 605 of the latch assembly 125. In some examples, the latch 605 may include a first end defining a recess configured to engage with the retention bearing 305 – e.g., as defined by a hook 610 (or hook portion), as shown. In some examples, opposite the first end, an opposite end of the latch 605 may define a mounting point 615. For example, a biasing element (e.g., a spring) 620 may be secured between the mounting point 615 of the latch 605 and the mounting bracket 235. In some examples, the biasing element 620 may be configured to automatically return the latch 605 to a home position following the release of the handle 505 by a user.

In some examples, the latch 605 may be secured to the mounting bracket 235 via a pivot pin 625. The pivot pin 625 may be arranged at about a midpoint of the latch 605 in order to permit pivotal movement of the latch 605. Further, in some examples, the latch 605 may include a protrusion 630, which is configured to engage with a corresponding embossed portion of the handle 505. For example, the embossed portion of the handle 505 is configured to contact the protrusion 630 so that movement of the handle in the direction shown by arrow 635 rotates the latch 605 about the pivot pin 625 (e.g., to release the hook 610 from the retention bearing 305).

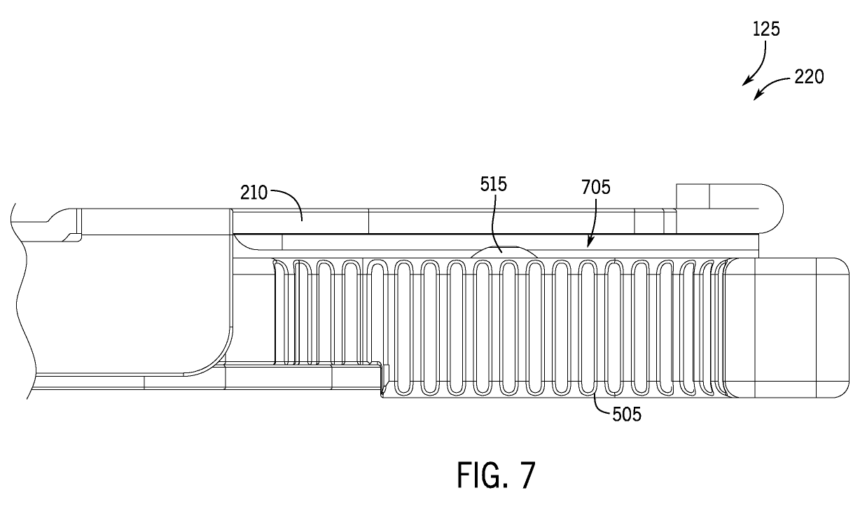

As can be seen in FIG. 7, a gap 705 may be formed between the handle 505 and the second rail 210. In this regard, the rivets 515 securing the handle 505 to the mounting bracket 235 may sometimes extend beyond the outer periphery of the handle 505 (e.g., protrude laterally on the slide assembly, past a face of the handle 505). In some examples, the gap 705 may not only provide basic clearance for movement of the handle 505, but may also permit some degree of deformation of the server slides 120 (e.g., lateral deformation) without causing contact between the handle 505 and the second rail 210. As a result, such deformation during operation would not tend to increase the force required to actuate the handle 505, and thus the latch assembly 125.

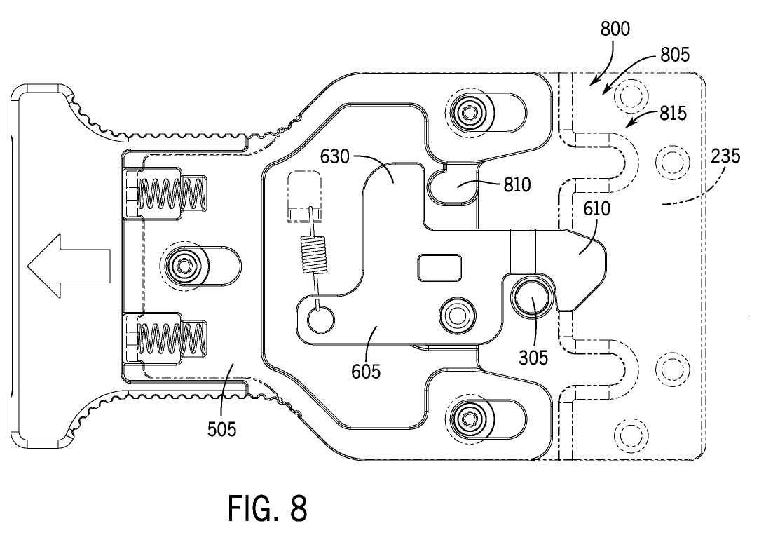

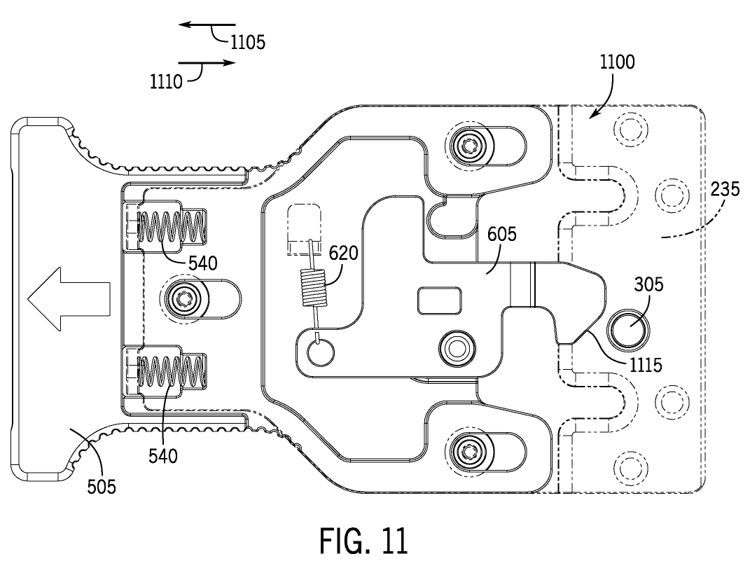

FIGS. 8-11 illustrate an example process for moving the server chassis 115 between the first position 140 and the second position 145 utilizing the latch assembly 125 described above with respect to FIGS. 2-7. At stage 800, shown in FIG. 8, the server chassis 115 may be in the first position 140 (e.g., the retracted position, as shown in FIG. 1) and the operator may desire to move the server chassis 115 into the second position 145 (e.g., the extended position for maintenance, replacement, etc. , as shown in FIG. 1). While the chassis is in the first position 140, the latch assembly 125 may be in the first (engaged) position 805 to prevent movement of the first rail 205 relative to the second rail 210 via contact between the latch 605 and the retention bearing 305. For example, the hook 610 of the latch 605 may surround a portion of the retention bearing 305 to secure the retention bearing 305 (or a differently configured latch may engage the retention bearing 305 at a corresponding different hook or shoulder). Further, an embossed portion 810 of the handle 505 may be in contact with, but not applying a force to, the protrusion 630 of the latch 605.

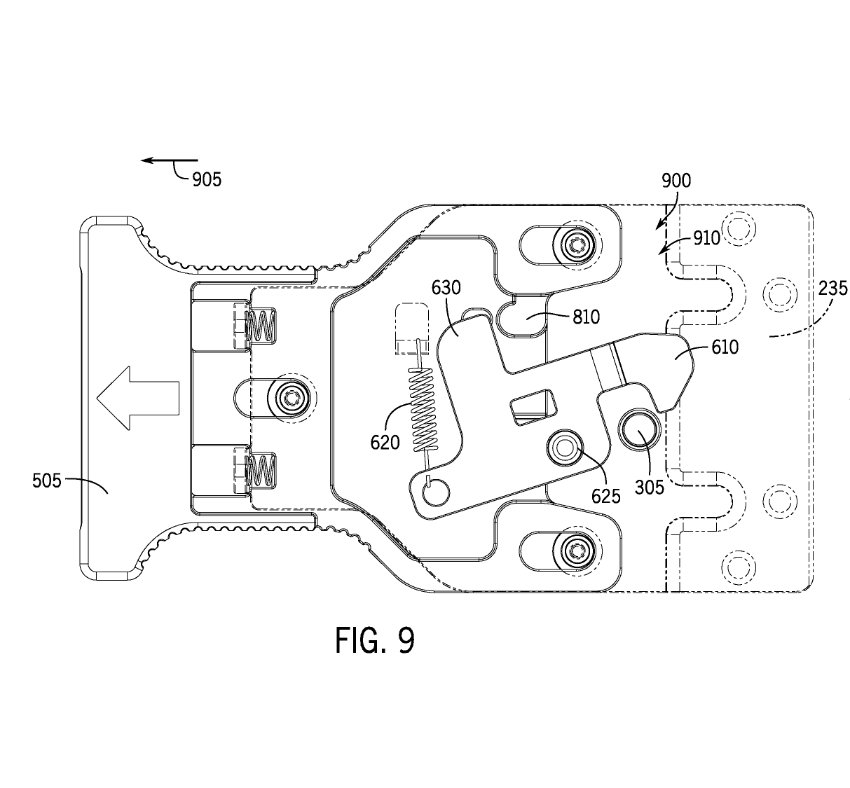

At stage 900, shown in FIG. 9, to release the first rail 205 from the second rail 210, the operator may grasp the handle 505 and pull the handle 505 in the direction shown by arrow 905, from the first position 815 (see, e.g., FIG. 8) to the second position 910. As the operator actuates the handle 505, the embossed portion 810 of the handle 505 applies a force to the protrusion 630 of the latch 605 to rotate the latch 605 about the pivot pin 625 (e.g., against the biasing force of the biasing element 620). Put differently, pulling the handle 505 forces the hook 610 of the latch 605 to begin to rotate out of contact with the retention bearing 305 (e.g., to disengage the latch assembly 125).

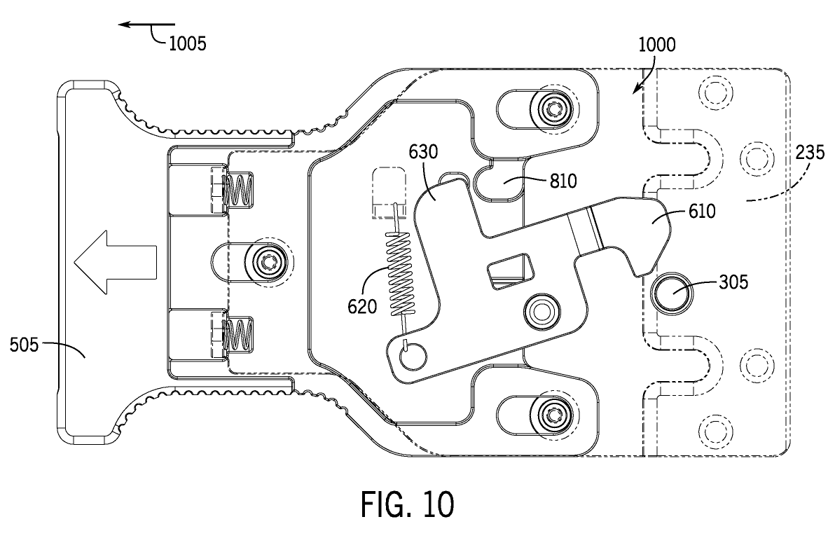

At stage 1000, shown in FIG. 10, as the operator continues to pull the handle 505 in the direction shown by arrow 1005, the second portion 410 of the retention bearing 305 may rotate about the first portion 405, which may reduce the pulling force required by the operator to disengage the latch 605 from the retention bearing 305. In other words, the rotation of the second portion 410 of the retention bearing 305, via engagement by the latch 605, can help to move the latch circumferentially around the retention bearing 305 from the first latch position toward the second latch position.

At stage 1100, once the latch 605 has been disengaged from the retention bearing 305, the operator may continue to apply a force to the handle 505 in the direction shown by arrow 1105. With the latch 605 clear of blocking contact with the retention bearing 305, the operator may thus move (e.g., pull) the server chassis 115 out of the server rack 105 from the first position 140 to the second position 145.

In some examples, once the operator has moved the server chassis 115 into the second position 145, the operator may release the handle 505. Once the operator releases the handle 505, the biasing elements 540, 620 may automatically return the handle 505 and the latch 605 to the first position 805. Correspondingly, the handle 505 may automatically return to the first position 815. At this time, even with the handle 595 and the latch 605 in the respective first positions 805, 815, the operator may be able to return the server chassis 115 to the first position 140, without needing to actuate the handle 505.

For example, the operator may apply a force in the direction shown by arrow 1110 (e.g., a pushing force) to retract the first rail 205 into the second rail 210. In some examples, as the first rail 205 retracts into the second rail 210, a chamfered surface 1115 of the latch 605 contacts the retention bearing 305, which rotates the latch 605 and extends the biasing element 620. As a result, the first rail 205 is able to slide within the second rail 210 without actuating the handle 505. Further, once the retention bearing 305 reaches the hook 610 of the latch 605, the biasing element 620 may bias the latch 605 into contact with the retention bearing 305 (e.g., into the first position 805) to automatically secure the first rail 205 relative to the second rail 210. In this regard, as well, movement of the latch 605 into the first position 805 to lock the first rail 205 can be further facilitated by corresponding rotation of the second portion 410 of the retention bearing, via contact force from the latch 605.

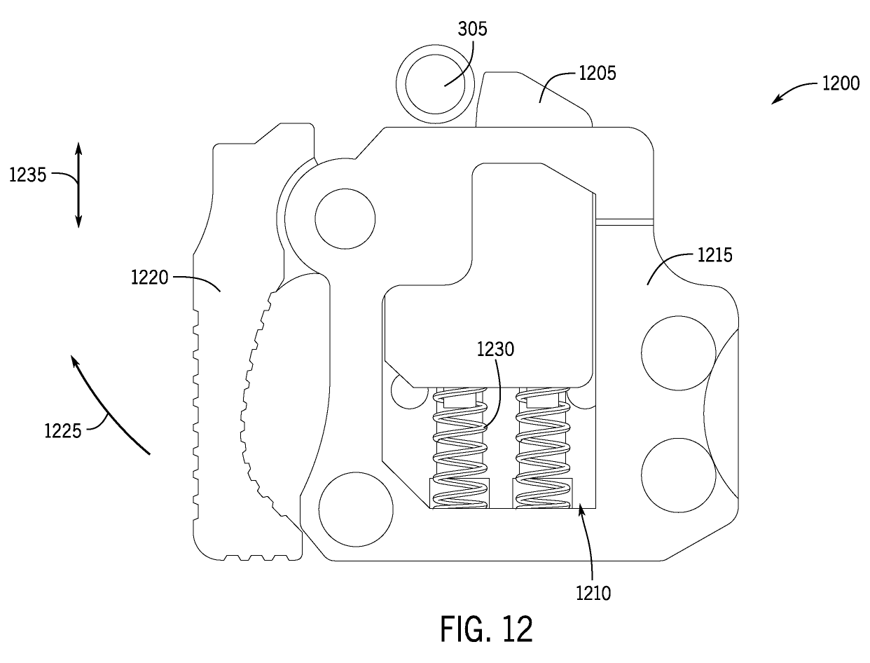

FIGS. 12-14 illustrate other examples of latch assemblies 1200, 1300, and 1400 for use with the server slides 120. As will be recognized, the latch assemblies 1200, 1300, and 1400 share a number of components in common with and operate in a similar fashion to the examples illustrated and described previously (e.g., the latch assembly 125). For the sake of brevity, these common features will not be again described below in detail. Rather, previous discussion of commonly named or numbered features, unless otherwise indicated, also applies to example configurations of the latch assemblies 1200, 1300, and 1400.

With reference to FIG. 12, the latch assembly 1200 includes a latch 1205 arranged within an opening 1210 defined by a mounting bracket 1215. In some examples, the latch 1205 may be configured to abut the retention bearing 305 (e.g., to prevent extension of the server slides 120). However, the latch 1205 may be disengaged from the retention bearing 305 via movement of a handle 1220 (e.g., between first and second positions) to permit extension of the server slides 120.

In some examples, unlike the latch assembly 125, the latch assembly 1200 may include a latch 1205 that moves linearly (e.g., vertically as shown) in response to movement (e.g., rotational movement) of the handle 1220 between first and second positions. For example, rotation of the handle as shown by arrow 1225 may drive the latch 1205 downward (e.g., within the opening 1210) against the biasing force of one or more biasing elements 1230. In some examples, during movement of the latch 1205, the second portion 410 of the retention bearing 305 may rotate, which may reduce the amount of force required to be applied to the handle 1220 in order to disengage the latch assembly 1200.

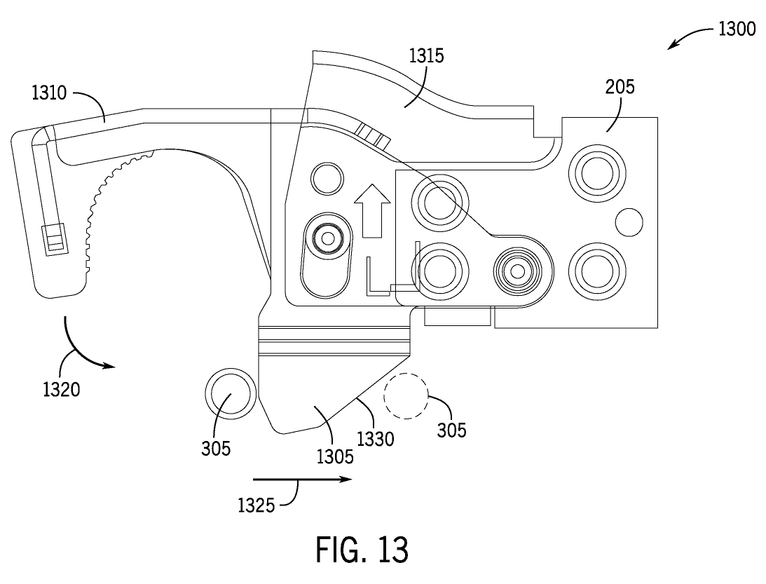

Looking at FIG. 13, the latch assembly 1300 includes a latch 1305 that may be integrated into a handle 1310. Further, the handle 1310 (e.g., including the latch 1305) may be rotationally secured to a mounting bracket 1315 so that rotational movement of the handle 1310 (e.g., as shown by arrow 1320) corresponds to rotational movement of the latch 1305.

In some examples, as the first rail 205 is moved from an extended position to a retracted position (e.g., pushed in the direction shown by arrow 1325), the retention bearing 305 may slide along a chamfered edge 1330 of the latch 1305. However, due to the rotational characteristics of the retention bearing 305, the force required to push in the first rail 205 may be reduced.

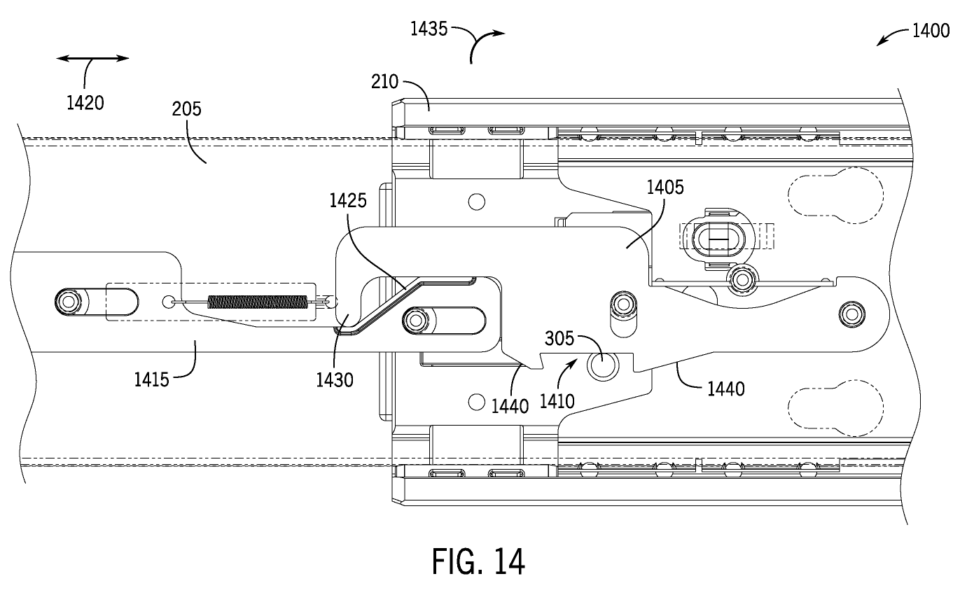

The latch assembly 1400 of FIG. 14 includes a latch 1405 that may be rotationally secured to the second rail 210, with a handle 1415 that may be slidably secured to the first rail 205 (e.g., slidable in the directions shown by arrow 1420). Thus, similar to the latch assembly 125, slidable movement of the handle 1415 may correspond to rotational movement of the latch 1405.

In some example, the latch 1405 may define a nose portion 1430 (e.g., a hooked nose portion) at one end that may engage with an angled portion 1425 at an end of the handle 1415. Thus, slidable movement of the handle 1415 may move the nose portion 1430 of the latch 1405 along the angled portion 1425 of the handle 1415, which may generate rotation of the latch 1405 as shown by arrow 1435 (e.g., to move the latch 1405 between first and second latch positions).

In some examples, as the latch rotates between first and second latch positions, the retention bearing 305 may be released from within a cutout 1410 defined by the latch 1405 (e.g., to permit extension of the server slides 120). Further, in some examples, when retracting the server slides 120, the retention bearing 305 may contact one or more angled guide edges 1440 on opposing sides of the cutout 1410. In some examples, due to the rotational characteristics of the retention bearing 305, the force required to push in the first rail 205 may be reduced.

In some implementations, devices or systems disclosed herein can be utilized, manufactured, or installed using methods embodying aspects of the invention. Correspondingly, any description herein of particular features, capabilities, or intended purposes of a device or system is generally intended to include disclosure of a method of using such devices for the intended purposes, a method of otherwise implementing such capabilities, a method of manufacturing relevant components of such a device or system (or the device or system as a whole), and a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of.” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

As used herein, unless otherwise defined or limited, directional terms are used for convenience of reference for discussion of particular figures or examples. For example, references to downward (or other) directions or top (or other) positions may be used to discuss aspects of a particular example or figure, but do not necessarily require similar orientation or geometry in all installations or configurations.

Also as used herein, unless otherwise limited or defined, “substantially parallel” indicates a direction that is within ± 12 degrees of a reference direction (e.g., within ± 6 degrees), inclusive.

Also as used herein, unless otherwise limited or defined, “substantially perpendicular” indicates a direction that is within ± 12 degrees of perpendicular a reference direction (e.g., within ± 6 degrees), inclusive.

Also as used herein, unless otherwise limited or defined, “integral” and derivatives thereof (e.g., “integrally”) describe elements that are manufactured as a single piece without fasteners, adhesive, or the like to secure separate components together. For example, an element stamped, cast, or otherwise molded as a single-piece component from a single piece of sheet metal or using a single mold, without rivets, screws, or adhesive to hold separately formed pieces together is an integral (and integrally formed) element. In contrast, an element formed from multiple pieces that are separately formed initially then later connected together, is not an integral (or integrally formed) element.

Additionally, unless otherwise specified or limited, the terms “about” and “approximately,” as used herein with respect to a reference value, refer to variations from the reference value of ± 15% or less, inclusive of the endpoints of the range. Similarly, the term “substantially equal” (and the like) as used herein with respect to a reference value refers to variations from the reference value of less than ± 10%, inclusive. Where specified, “substantially” can indicate in particular a variation in one numerical direction relative to a reference value. For example, “substantially less” than a reference value (and the like) indicates a value that is reduced from the reference value by 10% or more, and “substantially more” than a reference value (and the like) indicates a value that is increased from the reference value by 10% or more.

Also as used herein, unless otherwise limited or specified, “substantially identical” refers to two or more components or systems that are manufactured or used according to the same process and specification, with variation between the components or systems that are within the limitations of acceptable tolerances for the relevant process and specification. For example, two components can be considered to be substantially identical if the components are manufactured according to the same standardized manufacturing steps, with the same materials, and within the same acceptable dimensional tolerances (e.g., as specified for a particular process or product).

Unless otherwise specifically indicated, ordinal numbers are used herein for convenience of reference, based generally on the order in which particular components are presented in the relevant part of the disclosure. In this regard, for example, designations such as “first,” “second,” etc., generally indicate only the order in which a thus-labeled component is introduced for discussion and generally do not indicate or require a particular spatial, functional, temporal, or structural primacy or order.

The previous description of the disclosed embodiments is provided to enable any person skilled in the art to make or use the invention. Given the benefit of this disclosure, various modifications to these embodiments will be readily apparent to those skilled in the art, and the principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A server slide, comprising:
a first rail;
a second rail telescopically engaged with the first rail; and
a latch assembly secured to a first end of the first rail, the latch assembly including:
a latch that is biased toward a first latch position and movable between the first latch position and a second latch position;
a retention bearing including a fixed portion and a rotatable portion, the rotatable portion circumferentially surrounding the fixed portion to be rotatable around the fixed portion; and
a handle that is moveable between a first handle position and a second handle position to move the latch from the first latch position to the second latch position;
with the first and second rails in a locked configuration, the latch in the first latch position and the handle in the first handle position: the latch engaging the retention bearing at the rotatable portion to prevent telescopic movement of the first rail relative to the second rail in a first direction; and
as the handle is moved from the first handle position to the second handle position: the rotatable portion rotating to release the latch from engagement with the retention bearing, to permit telescopic movement of the first rail relative to the second rail in the first direction.

2. The server slide of claim 1, wherein a biasing element biases the latch into engagement with the retention bearing in a biasing direction that is transverse to the telescopic movement of the first rail.

3. The server slide of claim 1, wherein the handle includes a body portion engages the latch during sliding movement of the handle relative to the first rail to move the latch between the first and second latch positions.

4. The server slide of claim 3, wherein the handle includes:
a grip portion that extends from the body portion; and
an embossed portion that engages the latch to pivot the latch relative to the retention bearing during sliding movement of the handle.

5. The server slide of claim 3, wherein the rotatable portion of the retention bearing is configured to rotate in response to the sliding movement, to disengage the latch from the retention bearing.

6. The server slide of claim 3, wherein the handle is secured to the first rail with a mounting bracket secured to and extending from the first end of a main body of the first rail.

7. The server slide of claim 6, wherein the latch is pivotally secured to the mounting bracket via a fastener, and wherein the fastener forms a pivot point about which the latch rotates.

8. The server slide of claim 6, wherein the handle is slidably secured to the mounting bracket via a fastener, and wherein the fastener slides within a slot defined by the handle during movement of the handle between the first and second positions.

9. The server slide of claim 1, wherein a first end of the latch includes a chamfered surface and a hook, the hook configured to surround a portion of the retention bearing to prevent telescopic movement of the first rail relative to the second rail.

10. The server slide of claim 9, wherein the chamfered surface of the latch contacts the retention bearing to guide the retention bearing into the hook of the latch during telescopic movement of the first rail relative to the second rail in a second direction.

11. A method of operating a server slide, the method comprising:
engaging a handle of a latch assembly in a first position, in which the latch assembly prevents telescopic movement of a first rail relative to a second rail in a first direction;
sliding the handle from the first position to a second position, to disengage a latch of the latch assembly from a rotatable portion of a retention bearing, the retention bearing including a fixed portion that is circumferentially surrounded by the rotatable portion; and
with the handle in the second position, pulling the handle of the latch assembly to move the server slide from a retracted position to an expanded position.

12. The method of claim 11, further comprising:
rotating the rotatable portion of the retention bearing during disengagement of the latch from the retention bearing.

13. The method of claim 12, wherein sliding the handle of the latch assembly urges the latch into the rotatable portion of the retention bearing to rotate the rotatable portion and thereby move the latch of the latch assembly against a biasing force of a biasing element that biases the latch into engagement with the retention bearing.

14. The method of claim 11, wherein sliding the handle of the latch assembly pivots the latch of the latch assembly about a pivot point formed by a fastener securing the latch to a mounting bracket extending from a first end of the first rail.

15. The method of claim 14, further comprising:
pivoting the latch about the pivot point during movement of the handle from the first position to the second position via contact between an embossed portion of the handle and the latch.

16. The method of claim 15, wherein sliding movement of the handle between the first position and the second position corresponding to pivoting movement of the latch between an engaged position and a disengaged position.

17. The method of claim 11, wherein a first end of the latch includes a chamfered surface and a hook portion.

18. The method of claim 17, wherein the chamfered surface of the latch contacts the retention bearing to guide the retention bearing into the hook portion during telescopic movement of the first rail relative to the second rail in a second direction.

19. A latch assembly for telescoping engagement of a first rail and a second rail, the latch assembly including:
a latch that includes a latch recess, the latch being biased toward a first latch position and secured to the first rail to be movable between the first latch position and a second latch position; and
a retention bearing including a fixed portion secured to the second rail, and a rotatable portion circumferentially surrounding the fixed portion to be rotatable around the fixed portion;
the latch, in the first latch position, being aligned to receive the rotatable portion into the latch recess to secure the first rail against telescoping movement relative to the second rail;
the latch, in the second latch position, being aligned to clear the retention bearing to permit telescoping movement of the first rail relative to the second rail; and
with the latch in the first latch position and the rotatable portion received into the latch recess, the rotatable portion being rotatable by the latch, to move the latch circumferentially around the retention bearing from the first latch position toward the second latch position.

20. The latch assembly of claim 19, further comprising:
a handle that is translatable between a first handle position and a second handle position to move the latch circumferentially around the retention bearing from the first latch position to the second latch position.
